(19) United States
(12) Patent Application Publication
(10) Pub. No.: US 2005/0185496 A1
(43) Pub. Date: Aug. 25, 2005

(54) Intelligent solid state disk

(76) Inventor: Paul Kaler, Houston, TX (US)

Correspondence Address: Robert C. Strawbrich, 12415 Carlton Oaks Street, Tomball, TX, 77377, US

(21) Appl. No.: 11/059,789

(22) Filed: Feb. 17, 2005

Related U.S. Application Data
(60) Provisional application No. 60/547,217, filed on Feb. 24, 2004.

(51) Int. Cl. G11C 8/00

(52) U.S. Cl. 365/230.06

(57) ABSTRACT

A solid state disk (SSD) device, which is coupled to a host computer system, includes a non-volatile storage module (NVSM) and a volatile memory (VM). The SSD is intelligently controlled to process I/O requests received from the host, including writing data specified in a WRITE request to one or more address locations of the VM specified by the request, recording the data written to each address location of the VM as changed with respect to data stored in the NVSM for each address location, and replicating the changed data to the NVSM when not processing I/O requests from the host.

### BACKGROUND

This application claims the benefit of U.S. Provisional Application No. 60/547,217, filed Feb. 24, 2004.

Non-volatile storage is essential to virtually all computer systems, from notebooks to desktops to large data centers employing clusters of servers. Non-volatile storage serves as a secure data repository which prevents data loss in the event of an unexpected interruption in primary power. Some common forms of non-volatile storage are packaged as non-volatile storage modules (NVSM) that can employ a magnetic disk (under control of a magnetic disk drive), flash memory components, or even magnetic tape (under control of a magnetic tape drive) as the non-volatile storage medium for the module.

One of the downsides of non-volatile storage is that it is relatively slow to access compared to volatile forms of memory such as DRAM (Dynamic Random Access Memory). Thus, virtually all computer systems also include volatile memory (VM) in which to temporarily store data for faster access. Typically, code for executing application programs and data recently used by active applications are stored to and retrieved from the non-volatile storage and stored in the VM for faster access.

Recently, a hybrid form of storage has been developed that seeks to provide the persistence of non-volatile storage but an access speed comparable to VM. This form of storage is commonly known as a solid state disk (SSD). The SSD typically includes DRAM or some other form of VM and an NVSM that employs a non-volatile storage medium such as a magnetic disk, flash memory or the like. The SSD also typically includes a back-up or secondary power source such as a battery. The internal battery supply is used in the event that primary power is lost, with sufficient capacity to continue refreshing the VM while all of the data stored therein is saved off to the NVSM. Once primary power is restored, the data can be retrieved and stored back into the VM for access by the host computer system to which it is coupled.

To ensure reliability, it is critical that sufficient battery power is maintained to accomplish the backing up of the data in the VM of the SSD to the NVSM. To ensure a minimum down time after a loss of power, it is also desirable to minimize the time necessary to repopulate the VM from the NVSM.

### BRIEF DESCRIPTION OF THE DRAWINGS

For a detailed description of embodiments of the invention, reference will now be made to the accompanying drawings in which:

FIG. 1 is a block diagram that illustrates various features of a solid state disk (SSD), including some features by which the SSD operates in accordance with an embodiment of the present invention; and

FIGS. 2-9 are process flow diagrams illustrating embodiments of the control process of the present invention.

### NOTATION AND NOMENCLATURE

Certain terms are used throughout the following description and in the claims to refer to particular features, apparatus, procedures, processes and actions resulting therefrom. Those skilled in the art may refer to an apparatus, procedure, process, result or a feature thereof by different names. This document does not intend to distinguish between components, procedures or results that differ in name but not function. Moreover, those of skill in the art will recognize that the procedural flow diagrams illustrating embodiments of the invention are intended solely to illustrate the general functionality of the invention are not intended to depict a strict functional sequence. For example, those of skill in the art will recognize that certain of the processes run in parallel with one another or are susceptible to being run in a different order than that depicted by the flow diagrams disclosed herein. Thus, the functional diagrams are only intended to communicate the general functionality of the disclosed invention and are but one possible representation of that functionality. Finally, in the following discussion and in the claims, the terms “including” and “comprising” are used in an open-ended fashion, and thus should be interpreted to mean “including, but not limited to . . . .”

### DETAILED DESCRIPTION

The following discussion is directed to various embodiments of the invention. Although one or more of these embodiments may be preferred, the embodiments disclosed should not be interpreted as, or otherwise be used for limiting the scope of the disclosure, including the claims, unless otherwise expressly specified herein. In addition, one skilled in the art will understand that the following description has broad application, and the discussion of any particular embodiment is meant only to be exemplary of that embodiment, and not intended to intimate that the scope of the disclosure, including the claims, is limited to that embodiment.

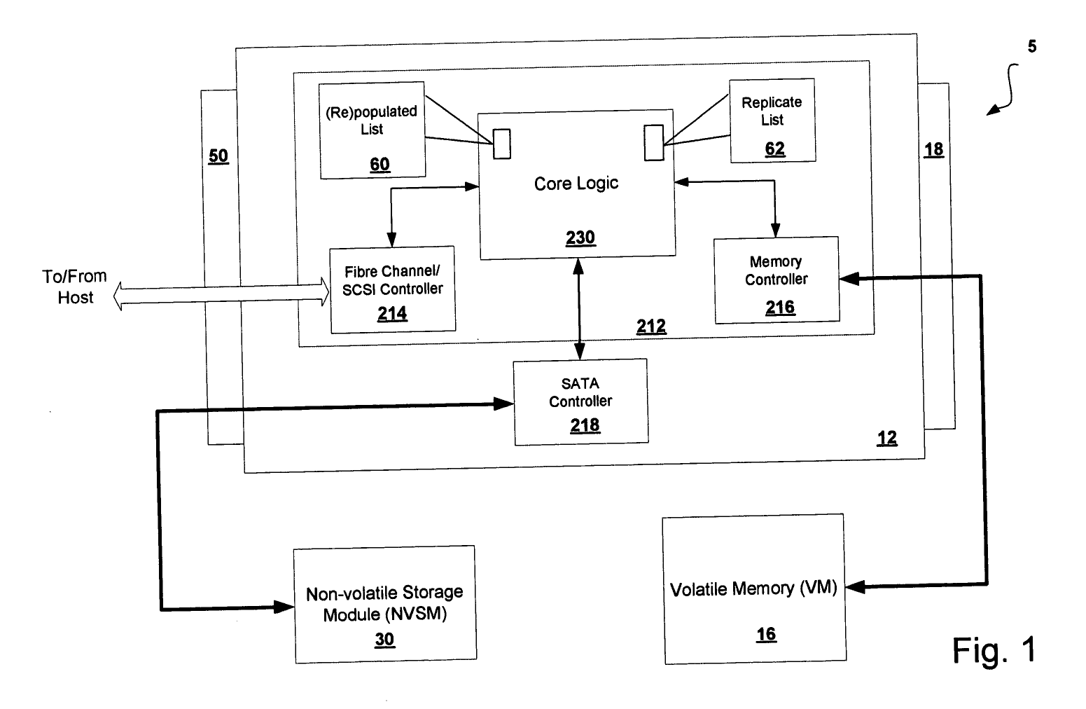

FIG. 1 is a block diagram that illustrates various features of a solid state disk (SSD) 5 that may be used to implement various embodiments of the invention. SSD 5 may be coupled to a host computer system (not shown) either directly, or indirectly through one or more intermediate devices such as a storage array controller or the like. In an embodiment, the SSD 5 includes an SSD controller 12 that comprises several components mounted on a PCB (printed circuit board). The SSD 5 further includes a non-volatile storage module (NVSM) 30 that can include a non-volatile storage medium such as a magnetic disk, flash memory, magnetic tape or the like. The controller 12 can be coupled to the host computer system and the NVSM 30 through backplane connector 50 as illustrated. The SSD 5 can further include a volatile memory (VM) 16 that can be comprised of volatile memory media components such as SRAM (static random access memory) or dynamic random access memory (DRAM). The term DRAM should be interpreted for purposes of this disclosure to include any one of a number of DRAM variations such as SDRAM (synchronous DRAM), DDR (double data rate SDRAM), DDR2 (double data rate 2 SDRAM), and equivalents thereof. The PCB upon which the SSD controller 12 components are mounted can be coupled to the PCB upon which the VM 16 storage components are mounted through a connector such as sandwich connector 18.

An embodiment of the SSD controller 12 may further include a core logic block 230 that communicates with the host computer via a channel interface 214 that conforms to a standard channel interface such as Fibre Channel, SCSI or equivalent. Core logic 230 may also communicate with the storage media of NVSM 30 through an interface controller 218 that implements a standard such as SATA or an equivalent thereof appropriate to the type of media employed within the NVSM 30. Core logic 230 can also communicate with the VM 16 through a memory controller 216. Core logic 230 can be implemented in the form of an FPGA (field programmable gate array), ASIC (application specific integrated circuit) or some other equivalent integrated circuit 212 technology.

In an embodiment, the core logic 230 can be implemented as a microcontroller that includes a processor that executes firmware stored in a small non-volatile memory by which to control the functioning of the SSD 5, or as a sequential state machine or some other form of sequential combinatorial logic. Those of skill in the art will recognize that the controllers 214, 216 and 218 can also be incorporated within the same integrated circuit 212 as the core logic 230, or can be implemented using any other physical partitioning of the functions as may be deemed preferable. The SSD 5 also includes a secondary or back-up power source, which is typically a battery (not shown). The secondary power source is typically engaged to supply power for certain tasks required to ensure an orderly shut-down during a loss of primary power. While primary power is present, the battery can be maintained substantially at full capacity by charging it using the primary power.

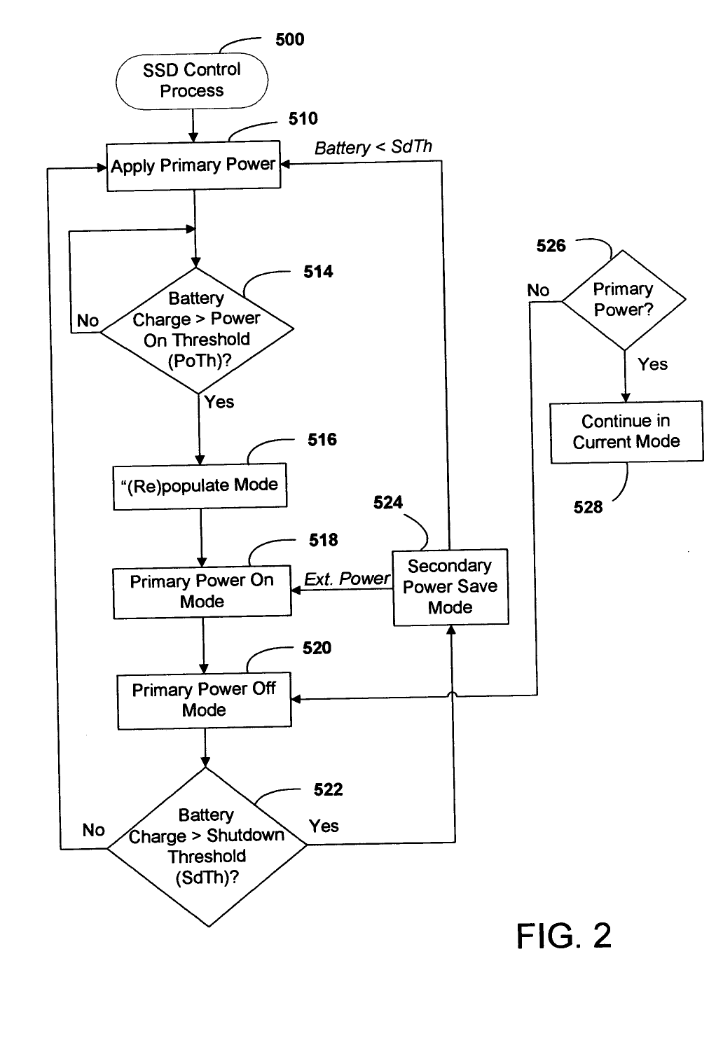

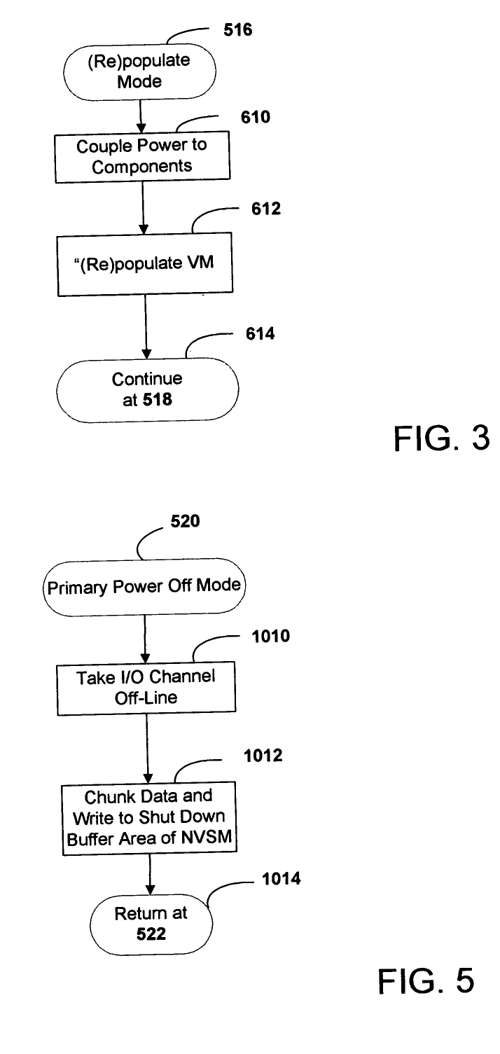

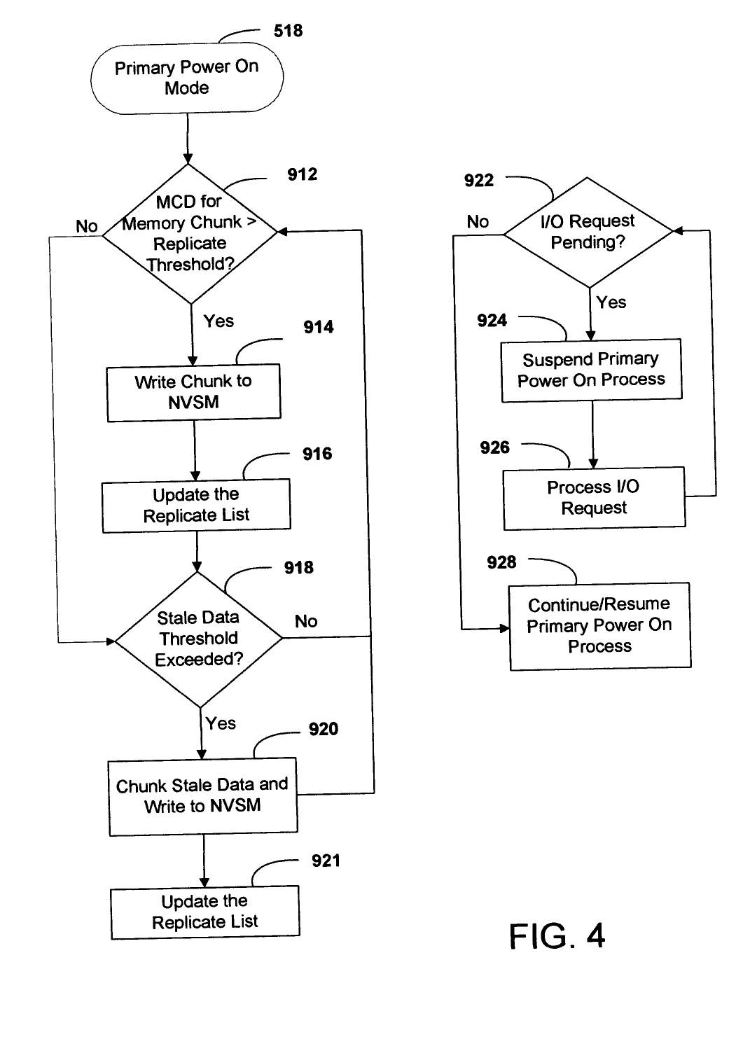

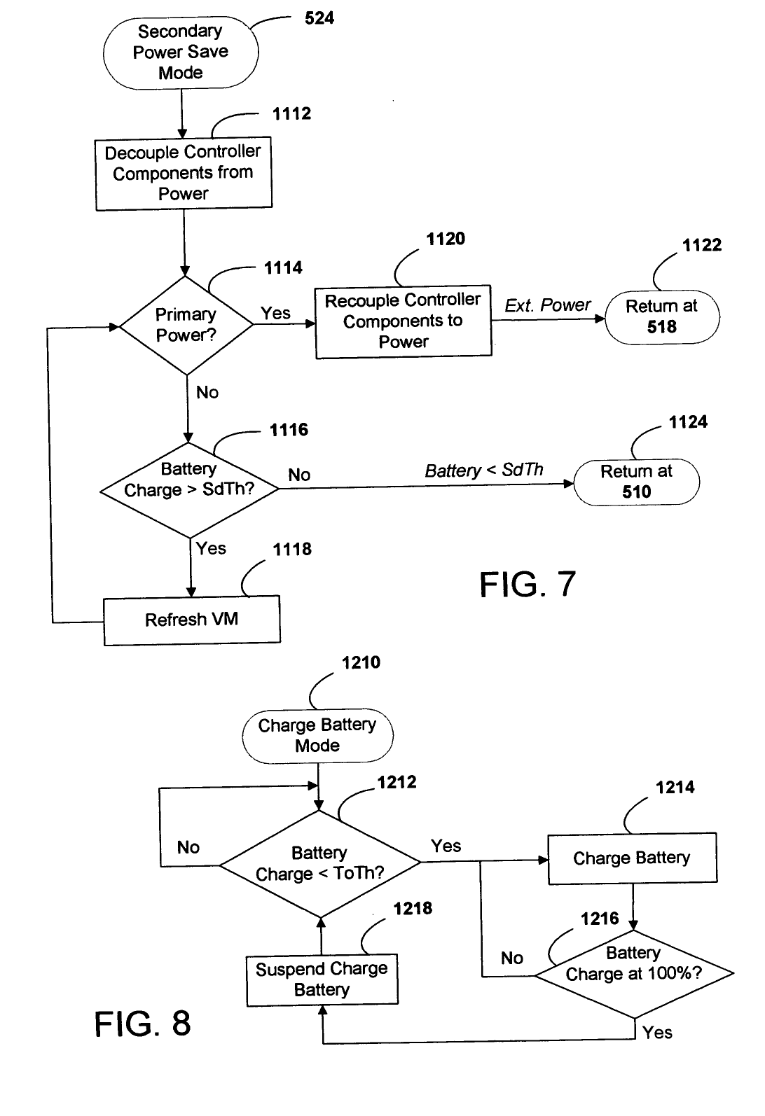

An embodiment of the control process 500, which is executed by the control logic 230 in conjunction with the other components of the SSD 5, is illustrated by the procedural control diagrams of FIGS. 2-9. In an embodiment, the control process 500 operates in four primary modes: (Re)populate mode 516, FIGS. 2, 3; Primary Power On mode 518, FIGS. 2, 4; Primary Power Off mode 520, FIGS. 2, 5; and Secondary Power Save mode 524, FIGS. 2, 7.

In (Re)populate mode 516, the SSD controller 12 populates (in the event a new NVSM 30 is provided with pre-loaded data) or repopulates (in the event that the SSD 5 is coming back up from a shutdown due to loss of primary power) the VM 16 with data stored in or on the NVSM 30 storage medium. The SSD controller 12 also processes Input/Output (I/O) requests from the host computer during the (re)population process so that the SSD 5 does not have to wait until the entire VM 16 has been (re)populated to begin serving the host computer.

In an embodiment, the (Re)populate mode 516 of the present invention minimizes the impact on system performance that heretofore has plagued previous SSD implementations endeavoring to service I/O requests from a host in parallel with the (re)population of the VM 16. In an embodiment, this can be accomplished by writing to the VM 16 data retrieved from the NVSM 30 in servicing a READ request. The fact that this data has been (re)populated in the process of servicing a READ request is recorded in a (Re)populated List 60, FIG. 1, which is maintained by Core Logic 230 of SSD controller 12. This eliminates the data retrieved as a result of processing a READ request from the data that still needs to be (re)populated from the NVSM 30 to the VM 16. Likewise, any data written to the VM 16 in processing a WRITE request from the host can be recorded in the (Re)populated List 60 as having been (re)populated. Finally, the data also can be (re)populated from the NVSM 30 to VM 16 in a manner that prioritizes data that was most recently or most often accessed prior to a shut-down. This information can be stored in association with the data when it is written to the NVSM 30. In this way, the SSD 5 can be brought on-line to service the host after a shut-down during the (re)population process (thereby minimizing system down time), while also minimizing the negative impact on I/O performance previously associated with (re)populating the data in parallel with handling I/O requests.

Once (re)population of the VM is complete, the SSD 5 operates in Primary Power On mode 518. In this mode, the controller 12 not only handles I/O requests for the host computer, but it also steadily replicates the data stored in the VM 16 to the NVSM 30 in between servicing pending I/O transactions. Replication serves to minimize the amount of data that must be written to the NVSM 30 during a shut-down. Replication also improves reliability in that it minimizes the amount of battery power required to write the data stored in VM 16 to the NVSM 30 during a shut-down. This in turn permits the SSD 5 to use the conserved battery power (while in Secondary Power Save mode 524) to continue refreshing the VM 16 after a shut-down. If primary power can be restored while sufficient battery power exists to keep the VM 16 refreshed or powered, the boot up process including (re)population will not be necessary and the system down time is kept to a minimum. In such a case, the SSD 5 can go straight back to Primary Power On mode 518. Any battery power that can be conserved during the shut-down write process can be made available to refresh or maintain the data stored in the VM 16 after the shut-down. This extends the time during which the SSD 5 can hold out for a restoration of primary power and a quick return to Primary Power On mode 518.

In addition, during Primary Power On mode 518, the data is replicated to the NVSM 30 from the VM 16 on a chunk by chunk basis. In an embodiment, writing a chunk (i.e. replicating that chunk of data) to the NVSM 30 storage media is precipitated when the controller 12 has detected that a certain percentage of that chunk of data has been overwritten through the execution of write requests from the host to the VM 16. This replicate threshold can be specified as percentage of the data of a chunk that has been changed (e.g. a percentage replicate threshold), or it can be given as an absolute number of megabytes of changed data (e.g. an MCD replicate threshold). Those of skill in the art will recognize that the percentage or amount for the replicate threshold, as well as the size of the chunks, can be varied to optimize the process depending upon other system variables. Thus the actual values of the replicate threshold and the chunk size can be varied without exceeding the intended scope of the invention. In the case where the NVSM 30 includes a magnetic disk as its storage medium, the replicate process ensures that the replicate writes to the magnetic disk of the NVSM 30 are particularly friendly to its disk drive by making them continuous and only after sufficient data has been overwritten to warrant them. Thus, replicate writes will not typically involve numerous random seeks on the disk. This therefore increases the reliability and longevity of a magnetic disk drive and its associated mechanics, as well as minimizing the write time for the data.

The controller 12 also monitors all chunks over time such that if certain chunks do not reach or exceed the replicate threshold level that would otherwise trigger a replication write to the NVSM 30 for those chunks within some period of time. Those chunks are also written periodically to the NVSM 30 upon the expiration of such a periodic stale data period, which could be once an hour for example. Those of skill in the art will recognize that this can be implemented on an individual chunk basis, or the SSD controller 12 could simply initiate a replicate write to the NVSM 30 for all chunks upon expiration of the stale data period.

Processing moves to the Primary Power Off mode 520 from the Primary Power On mode 518 when there is an interruption in the primary power supply. During this mode, the SSD controller 12 performs a shut-down process during which any data not replicated while the SSD 5 was in Primary Power On mode 518 must be written to the NVSM 30 using the secondary power source. In the case where NVSM 30 includes a magnetic disk as its storage medium, the outer portion of the disk (which is the fastest portion of the disk to access due to the higher tangential velocity of the tracks there) is reserved for the shut-down write process. This further minimizes the time necessary to save off the unreplicated data from the VM 16 to the NVSM 30 and thus further conserves the internal battery power.

In Secondary Power Save mode 524, which is entered upon completion of the shut-down process and if the battery has a charge level that meets or exceeds a shutdown threshold (SdTh), all components of controller 12 not required to maintain data in the VM 16 or to continue to monitor for the restoration of primary power and the current battery charge level can be disconnected from power to further conserve the battery power. The secondary power supplied by the internal battery is then used to refresh the VM 16 when its storage medium is DRAM, or to supply constant power if the storage medium is SRAM for example. If the primary power is restored while the internal battery still has sufficient charge to meet or exceed the shutdown threshold SdTh, the SSD 5 can return directly to the Primary Power On mode 518 without need for repopulating the VM 16 from the NVSM 30. If the battery charge level falls below SdTh, the SSD 5 ceases refreshing and/or maintaining the data stored in the VM 16 storage medium and shuts down. The controller 12 then awaits restoration of primary power at block 510. When primary power is restored, the SSD 5 proceeds to (Re)populate mode 516 once more, providing that the battery charge level at that time exceeds the predetermined primary power on battery threshold (PoTh). Otherwise the controller 12 waits until the battery charges to the PoTh before proceeding. In an embodiment, PoTh would typically be less than SdTh.

A more detailed discussion of an embodiment of the SSD control process 500 of the present invention is now presented with reference to FIGS. 2-7. Initially, primary power is applied to the SSD 5 at block 510. This can be subsequent to an interruption of the primary power, or it could be the first time the SSD 5 is booted up. Primary power is typically supplied from a standard external AC or DC power source but could also be supplied by a battery external to the SSD 5, such as in the case of a lap-top or notebook computer for example. At decision block 514, the secondary source of power typically provided by an internal back-up battery resident in the SSD 5 (and not shown in FIG. 1) is tested to determine if it has a charge level greater than the predetermined primary power on threshold capacity (PoTh). In an embodiment, this could be sufficient capacity to ensure that a worst case amount of unreplicated data can still be written from the VM 16 to the NVSM 30 in the event primary power is lost shortly after boot up. If the battery charge level is not at or above that threshold, the control process waits for the battery to charge to a level that meets the PoTh before proceeding to process block 516.

In an embodiment, the SSD battery is charged by Charge Battery process 1210, FIG. 8, which runs in parallel with the other processes and modes of FIG. 2. During this process, which runs in the presence of primary power, the internal battery is monitored continuously as indicated. If the internal battery's charge level is determined to be below some top-off threshold (ToTh) (for example, 95% of capacity) at decision block 1212, the battery is charged using the primary power source at 1214. If from there it is determined at decision block 1216 that the battery's charge level is substantially at 100% of capacity, the charging process is suspended at block 1218 and the battery is not charged until it is once again determined that the battery charge level has fallen below the ToTh at 1212.

Once it is determined that sufficient level of charge has been reached (i.e. battery charge level is greater than the PoTh), processing continues at (Re)populate mode 516. If primary power has been restored after an interruption of the primary supply, then the nature of the process is a repopulation of data. If the power is being applied to the SSD 5 for the first time or after insertion of a new NVSM 30 (or even a new storage medium within the NVSM 30), then the VM will essentially be populated with the data for the first time. Those of skill in the art will recognize that this distinction is semantic in nature, and only distinguishes between two scenarios involving the identical process: 1) data is retrieved from the NVSM 30 and stored in the VM 16 for the first time; and 2) data that was once stored in VM 16, was replicated to the NVSM 30 during Primary Power On mode 518, was temporarily written to the NVSM 30 during shutdown while in Primary Power Off mode 520, and is then retrieved and stored to VM 16 once primary power has been restored. Other than the foregoing distinction, the process connoted by the two terms is the same and thus the terms populate and repopulate are used interchangeably herein, often as (re)populate.

During (Re)populate mode (516, FIG. 3), primary power is coupled to all of the components of the controller 12, as well as VM 16 and NVSM 30 at block 610. This occurs in the event that certain of the components of the SSD 5 and controller 12 may be decoupled from the power supply during Secondary Power Save mode 524. The controller 12 then coordinates the (re)population of the VM 16 from the NVSM 30 at block 612 based on file list information that is associated with the data stored on or in the storage media of the NVSM 30, which includes appropriate address locations for the data in the VM 16.

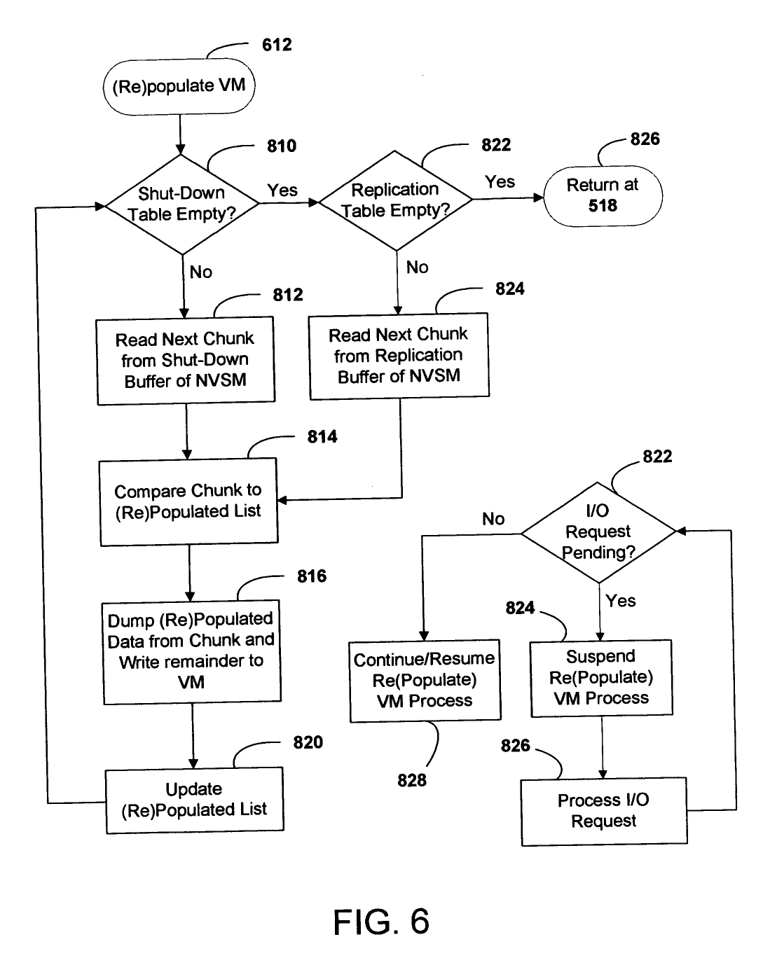

A more detailed description of an embodiment of the (Re)populate Memory process 612 is illustrated in FIG. 6. In an embodiment, the NVSM 30 includes a magnetic disk as its storage medium. The disk can be partitioned into at least two areas. The first can be called the shut-down buffer area and typically includes tracks at the outside of the disk, which has the greatest tangential velocity and thus is the fastest area of the disk to access. A second area can be called the replication buffer area of the disk, and this contains data that was written to the disk during the replication process of the Primary Power On mode 518. In this case, the data is written to the storage medium of NVSM 30 more as it is arranged in the VM 16 because it was replicated in the presence of primary power and thus time was not of the essence.

At decision block 810, the controller 12 first determines whether a Shutdown Table is empty that contains the file information for any data that was previously written to the NVSM 30 during a shut-down after loss of power. This file information can include the total amount of data written to the shutdown buffer and the memory address information for purposes of (re)population of the VM 16 to the proper locations. This file data can also include information concerning how recently the data was accessed and/or how often it has been accessed. In an embodiment, data can be chunked and organized in the table using this information giving priority to data that was most recently or most frequently accessed prior to the shutdown.

If the answer at 810 is No, then the next chunk of data as indicated in the shutdown table is retrieved from the shut-down buffer area of the disk, (or of whatever other storage medium that is used in the NVSM 30). At 814 the chunk is compared to file data stored in a list called the (Re)populated List (60, FIG. 1) that is recorded by the core logic 230 of the controller 12. If any of the data has already been previously (re)populated within the VM 16, that data is dropped from the chunk and only the data that is left is written to the VM 16 at 816. The core logic 230 then updates the (Re)populated List 60 to indicate that the data has been repopulated and processing continues at 810.

If the answer at 810 is Yes, a similar table called the Replication Table is consulted that contains file data for data that was previously replicated to the replication buffer area of the storage medium of the NVSM 30 during the Primary Power On mode (518, FIG. 1). The filed data in this table is substantially the same as that described for the Shutdown Table. Accordingly, the data in this table could be chunked and ordered in a manner that gives priority to (re)populating data that was most recently accessed, for example. If this table is not empty, the next chunk of data stored in this table is retrieved at 824 and the same process is then applied at blocks 814, 816 and 820 to this chunk as to the chunks retrieved from the shut-down buffer area of the NVSM 30 storage medium. If the data stored in the two tables is organized to prioritize data most recently accessed, the SSD 5 can get the data most likely to be accessed by the host repopulated more quickly than the more stagnant data. When both tables are empty, the entire VM 16 has been (re)populated and processing returns at Primary Power On mode 518, FIG. 1.

Also while the (re)populate VM process 616 is ongoing, the controller 12 is monitoring in parallel the I/O channel for I/O requests from the host (at 822, FIG. 6). If an I/O request is received from the host and is pending, the (Re)populate VM process 612, FIG. 6 is interrupted and suspended at 824. The controller 12 then handles the request at 826 and returns to see if any other requests are pending. If not, the (Re)populate VM process 612, FIG. 6 resumes from wherever it was suspended until the next I/O request is received. In this way, the SSD 5 is able to handle communications with the host even before the (re)populate mode has been completed.

In Primary Power On mode (518, FIG. 4), the controller also monitors in parallel the receipt of I/O requests from the host at 922. When an I/O request is pending, the Primary Power On process 518 is suspended at 924 and the I/O request is processed by the controller 12 at 926. Once the request is processed, if there are no further requests pending, the Primary Power On process 518 resumes or continues at 928 until another I/O request is received.

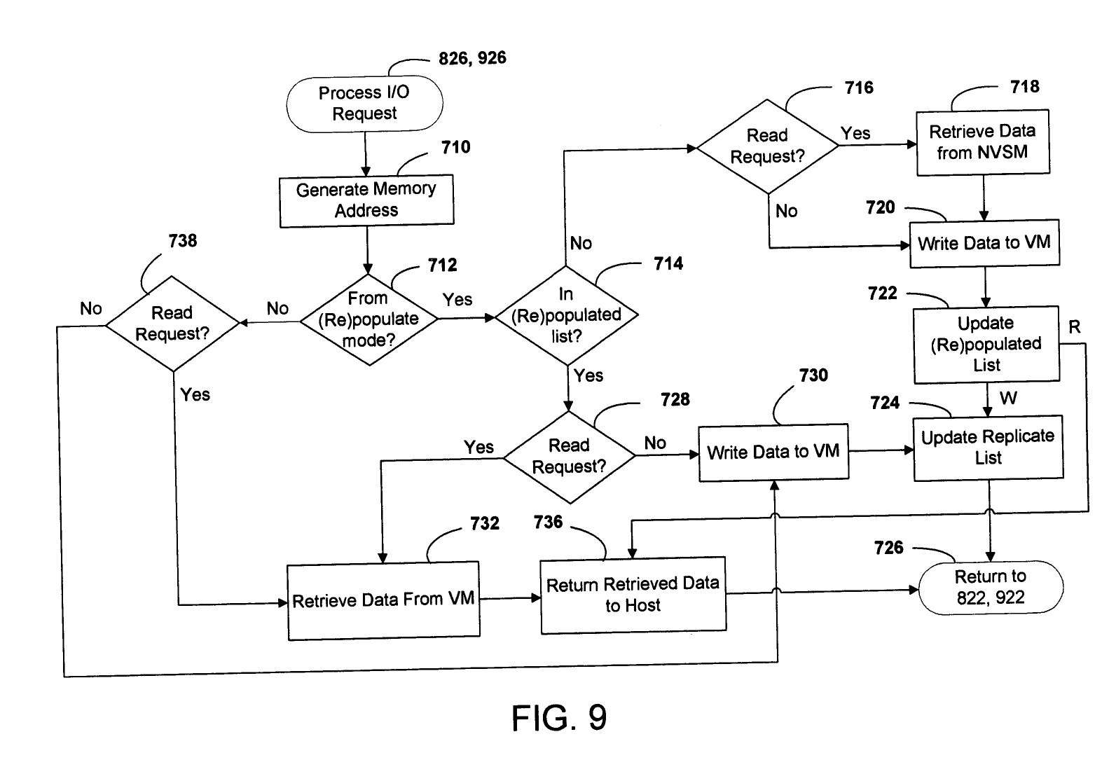

Before continuing with the discussion of the Primary Power On process 518, it will be informative to present the operation of how I/O requests are processed with reference to FIG. 9. This is because the processing of the I/O requests affects the replication process of the Primary Power On mode (518, FIG. 4) as well as the (Re)populate VM process (616, FIG. 6). As indicated, the Process I/O Request process 826, 926 can be called from either the (Re)populate VM process at 826 (FIG. 6) or during the replication process of the Primary Power On mode at 926 (FIG. 4). Regardless from which mode the Process I/O request is made, the controller 12 translates at block 710 the virtual address received with the request from the host to a memory address for accessing the VM 16. Those of skill in the art will recognize that this translation is typically required because the host typically employs virtual addressing, which must be translated to a real address of the VM 16. Nevertheless, the host still specifies the address locations of the VM 16 with its I/O requests, albeit through this address translation process.

If called from the Primary Power On mode 518, the answer at decision block 712, FIG. 9 is No and processing continues at decision block 738 where it is determined if the I/O request is a READ or a WRITE. If it is a READ, the answer at 738 is Yes and processing continues at 732. Because (re)population of the VM 16 has already been completed if the controller 12 is in Primary Power On mode 518, the controller 12 knows that the data is in the VM 16 and thus it is retrieved at 732 from the VM 16 and returned to the host at 736. Processing then returns to 922, FIG. 6. If the request is a WRITE, the answer at 738 is No and the data is written to the VM 16 at the generated memory address. The Replicate List 62 is then updated at 724 within the appropriate chunk to record that the data at this location has been overwritten and needs to be replicated.

If the I/O Request process is called from the (Re)populate VM process at 826, the answer at 712 is Yes. If the data for that address is not recorded in the (Re)populated List 60, then the answer at 714 is No and this indicates that the data sought by the host has yet to be (re)populated. If the request is a READ, the answer at 716 is Yes and the data is retrieved directly from the NVSM storage medium at 718. The controller then writes the retrieved data from the NVSM 30 to its appropriate location in the VM 16 and the (Re)populated List 60 is updated at 722 to reflect that this data has now been (re)populated. Because it is a READ request, it follows the R path from block 722 to block 736 where the retrieved data is then provided to the host. Processing then returns to 822 at block 726.

If the request is a WRITE, then the answer back at block 716 is No. The data provided by the host with the WRITE request is written to the VM 16 at block 720 and the (Re)populated List 60 is updated at 722 to record that the data should not be (re)populated from the NVSM 30 any longer; the data currently stored in the NVSM 30 for this location is now stale. Processing follows the path marked W and the Replicate List 62 is also updated at 724 to note that this data location has been overwritten with respect to the data that is stored in or on the NVSM 30 storage medium and that it should be written to the VM 16 during the replication process.

Back at block 714, if the memory location(s) specified with the pending request is (are) in the (Re)populated List 60, the answer is Yes. Processing then continues at 728 where if the request is a READ, the answer is also Yes and data is retrieved from the VM 16 at block 732 and returned to the host. Because the data is not overwritten by the READ request and has already been (re)populated, neither the (Re)populated List 60 nor the Replicate List 62 needs to be updated. Processing continues at 726 where it returns to 822, FIG. 6. If the pending request is a WRITE, the answer is No at 728 and the data provided by the host is written to the VM 16 at the specified location(s). Because the WRITE process effectively overwrites the data stored in the NVSM 30 that is associated with the specified addresses location(s), it must be recorded in the Replicate List 62 so that the changed data is marked for replication back to the NVSM 30. Again, processing continues at 726 from where it returns to 822, FIG. 6.

Returning back to the Primary Power On mode 518 of FIG. 4, the controller monitors the replicate list 62 for chunks of data that have been modified by some percentage greater than a predetermined replicate threshold percentage or by some replicate threshold given in total amount of data changed (e.g. megabytes of changed data (MCD)). For example, in an embodiment, the replicate threshold could be when 80% or more of the data in a particular chunk has been overwritten. When this percentage threshold or total data changed threshold has been met or exceeded for a chunk in the Replicate List 62, the answer at 912 is Yes and the chunk is then replicated (i.e. written) to the NVSM 30 at 914. The Replicate List 62 is then updated at 916 to indicate that this chunk has been replicated and that the percentage of changed data for that chunk is back to zero.

The controller 12 also monitors those chunks with changed data that have not exceeded the replicate threshold over some predetermined period of time. When this time period has been exceeded, all stale chunks are written to the NVSM 30 at 920. Those of skill in the art will recognize that the data can be re-chunked to improve the efficiency of writing the stale data in accordance with algorithms the details of which are not pertinent to the embodiments of the present invention disclosed herein. Also as previously mentioned, the optimal values for the replicate threshold, the size of the chunks and the stale data period can vary depending upon the particular application, etc. Thus the actual values used are not specific to the embodiments disclosed herein.

With reference to FIG. 2, if primary power should be lost and this loss is detected at 526, processing will proceed to Primary Power Off mode 520. With reference to FIG. 5, processing proceeds to block 1010 where the I/O channel is taken off line so no further I/O requests from the host are permitted. This also helps to conserve the secondary battery power which is now being applied to the remaining controller 12 components as well as the VM 16 and NVSM 30. The next step is to chunk any data listed in the Replicate List 62 and write it to the shut-down buffer area of the NVSM 30 storage medium. In an embodiment, the storage medium is a magnetic disk and the shut-down buffer area includes the most outside tracks available on the physical disk. Once this process has been completed, processing returns at 1014 to decision block 522, FIG. 2.

At this point, it is determined whether the current battery charge level is still above the predetermined shutdown threshold level (SdTh). This threshold could be, for example, the amount of battery power required to handle a worst case shut-down write of replicated data to the NVSM 30 medium plus some safety margin. If the answer is No, the SSD controller 12 shuts down and awaits the restoration of primary power at 510. In the meantime, the Charge Battery mode 1210 also awaits restoration of the primary power source, as it cannot charge the internal secondary battery supply without it. If the answer is Yes at 522, processing continues at 524 where the controller enters Secondary Power Save mode 524.

With reference to FIG. 7, Secondary Power Save mode 524 begins at 1112 by decoupling all non-essential components from the internal secondary battery supply, except for example, those components necessary to refresh the VM 16 and to monitor primary power and internal battery charge level. Should primary power be restored while in Secondary Power Save mode 524, the controller components are recoupled to the primary power supply at 1120 and processing returns directly to Primary Power On mode 518 at block 1122. If power is not currently restored then the answer at 1114 is No and it is determined at 1116 if the battery charge level is still greater than the threshold SdTh. If Yes, processing continues at 1118 where the VM 16 is refreshed. Controller 12 continues to monitor for the restoration of primary power at 1114 and for the battery charge level to fall below the threshold SdTh at 1116. So long as the charge level of the secondary power source remains greater than SdTh, the controller continues to refresh or otherwise maintain the data stored in the media of VM 16. If the battery charge level is detected at 1116 to fall below SdTh, the controller 12 ceases to refresh or otherwise maintain the data in VM 16. Processing continues at 510, FIG. 2 where the controller 12 ceases activity except to monitor for the restoration of primary power at 510, FIG. 2. Those of skill in the art will recognize that if the VM 16 comprises storage media that does not require refreshing, but rather a steady power supply, the process described above will supply the constant supply rather than periodically refreshing the medium.

In summary, it can be noted that during Primary Power On mode 518, the Replicate List 62 records data to be replicated within defined chunks so that the controller 12 always knows what data needs to be updated to the NVSM 30. Replication of data can proceed on an ongoing basis whenever it is opportunistic to do so in between processing I/O requests. During the (Re)populate mode 516, the (Re)populate List 60 permits the controller 12 to handle I/O requests during the (re)populate memory process 616. As previously mentioned, replicating data to the NVSM 30 on an ongoing basis in between I/O requests helps to reduce the amount of data that needs to be written during a shut-down due to loss of primary power. This serves to conserve the internal secondary battery power for other purposes, including refreshing or maintaining the data in VM 16 long enough to see restoration of primary power. This permits the controller 12 to skip the (re)population process altogether. Moreover, by writing data in chunks when a large percentage of the chunk has been altered permits writes that are continuous and friendly to the storage medium of NVSM 30 (particularly when the medium is a magnetic disk). Finally, as previously mentioned, handling I/O requests during the (re)population process renders the SSD 5 available to the host sooner after a shutdown, further minimizing the time necessary to recover from a power loss and thus minimizing downtime.

1. A method of controlling a solid state disk (SSD) device, the SSD coupled to a host computer system and comprising a non-volatile storage module (NVSM) and a volatile memory (VM), said method comprising:
processing I/O requests received from the host, said processing further comprising:
writing data specified in a WRITE request to one or more address locations of the VM specified with the request; and
recording the data written to each address location of the VM as changed with respect to data stored in the NVSM for each address location; and
replicating the changed data to the NVSM when not processing I/O requests from the host.

2. The method of claim 1 wherein said recording further comprises:
partitioning the address locations of the VM into chunks;
determining when a threshold amount of data in any of the chunks has been changed; and
initiating replication of the changed data for each chunk having the threshold amount of changed data.

3. The method of claim 2 wherein said recording further comprises:
determining when one or more of the chunks have not reached the threshold amount of changed data before expiration of a predetermined time period and;
initiating replication of the changed data for those chunks not reaching the threshold amount of data after expiration of the predetermined time period.

4. The method of claim 1 wherein the SSD further comprises a secondary source of power, said method further comprising writing all unreplicated changed data to the NVSM upon loss of primary power using the secondary source of power.

5. The method of claim 4 wherein the secondary source of power comprises a rechargeable battery internal to the SSD.

6. The method of claim 4 wherein the unreplicated data is written to a shut-down buffer of the NVSM.

7. The method of claim 6 wherein the NVSM comprises a magnetic disk storage medium and the shut down buffer comprises tracks residing substantially at the outer portion of the magnetic disk.

8. The method of claim 4 further comprising:
maintaining the data currently stored in the VM using the secondary power source until the charge level of the secondary power source has fallen below a predetermined shutdown threshold or primary power has been restored to the SSD; and
decoupling one or more components of the SSD from the secondary power source not necessary to said maintaining.

9. The method of claim 8 wherein the VM comprises dynamic random access memory (DRAM) and said maintaining further comprises refreshing the DRAM using the secondary power source.

10. The method of claim 8 further comprising suspending said maintaining when the charge level of the secondary power source has fallen below the predetermined shutdown threshold before the primary power is restored.

11. The method of claim 8 further comprising suspending said processing of I/O requests and said replicating during said writing and said maintaining.

12. The method of claim 11 further comprising resuming said processing and said replicating when the primary power source is restored before the charge level of the secondary source has fallen below the predetermined shutdown threshold.

13. The method of claim 10 further comprising repopulating the written and replicated data from the NVSM to the VM after the suspending of said maintaining and after the primary power source has been restored.

14. The method of claim 13 further comprising resuming said processing I/O requests and said replicating in parallel with said repopulating until the VM is completely repopulated.

15. A method of controlling a solid state disk (SSD) device, the SSD coupled to a host computer system and comprising a non-volatile storage module (NVSM) and a volatile memory (VM), said method comprising: upon receiving primary power to the SSD:
populating the VM with data stored in the NVSM, the address locations for the data in the VM being associated with the data stored in the NVSM; and
processing pending I/O requests received from the host during said populating, said processing further comprising:
suspending said populating;
writing data specified with a WRITE request to one or more address locations of the VM specified with the request;
recording the written VM address locations of the WRITE request as changed;
recording the written VM address locations of the WRITE request as populated;
retrieving data from the VM when the address locations specified with a READ request are recorded as populated and returning the data to the host; and
retrieving data from the NVSM when one or more of the address locations of the READ request are not recorded as populated, writing the retrieved data to the VM, recording the address locations written with the retrieved data as populated and returning the data to the host.

16. The method of claim 15 wherein said populating further comprises:
accessing chunks of data from the NVSM;
comparing the address locations associated with the data comprising each chunk with the address locations recorded as populated;
dropping the data from the chunk associated with address locations; and
writing the remaining data to the VM at the associated address locations.

17. The method of claim 16 wherein the data being populated from the NVSM to the VM includes data that was previously replicated to the NVSM prior to a loss of primary power to the SSD and non-replicated data written from the VM to the NVSM during a shutdown of the SSD using secondary power.

18. The method of claim 17 wherein the non-replicated data is stored to a shut-down buffer of the NVSM and the replicated data is stored to a replication buffer of the NVSM.

19. The method of claim 18 wherein the NVSM comprises a magnetic disk storage medium and the shut down buffer comprises the most outside tracks available on the magnetic disk.

20. The method of claim 19 wherein the data is populated from the shut-down buffer first and the replication buffer second.

21. The method of claim 16 wherein the chunks of data are accessed from the NVSM on a most recently accessed basis.

22. The method of claim 16 wherein the data being populated from the NVSM to the VM is data that is being supplied to the SSD for the first time by storing data to the NVSM through an external source.

23. The method of claim 15 further comprising: after said populating is complete:
processing pending I/O requests received from the host during said populating, said processing further comprising:
writing data specified with a WRITE request to the address locations of the VM specified with the request;
recording the written VM address locations of the WRITE request as changed; and
replicating the changed data to their respective address locations in the NVSM when not processing pending I/O requests from the host.

24. The method of claim 23 wherein the SSD further comprises a secondary source of power, said method further comprising writing all un-replicated changed data to the NVSM upon loss of primary power using the secondary source of power.

25. The method of claim 24 further comprising:
maintaining the data currently stored in the VM using the secondary power source until the charge level of the secondary power source has fallen below a predetermined shutdown threshold or primary power has been restored to the SSD; and
decoupling one or more components of the SSD from the secondary power source not necessary to said maintaining.

26. The method of claim 25 further comprising resuming said processing and said replicating when the primary power source is restored before the charge level of the secondary source has fallen below the predetermined shutdown threshold.

27. A solid state disk (SSD) device comprising a non-volatile storage module (NVSM) and a volatile memory (VM), said SSD further comprising: a storage means for storing program instructions, the program instructions for:
processing I/O requests received from the host, said processing further comprising:
writing data specified in a WRITE request to one or more address locations of the VM specified by the request; and
recording the data written to each address location of the VM as changed with respect to data stored in the NVSM for each address location; and
replicating the changed data to the NVSM when not processing I/O requests from the host.

28. The SSD of claim 27 wherein said program instructions are further for:
partitioning the address locations of the VM into chunks;
determining when a threshold amount of data in any of the chunks has been changed; and
initiating replication of the changed data for each chunk having the threshold amount of changed data.

29. The SSD of claim 28 wherein said program instructions are further for:
determining when one or more of the chunks have not reached the threshold amount of changed data before expiration of a predetermined time period and;
initiating replication of the changed data for those chunks not reaching the threshold amount of data after expiration of the predetermined time period.

30. The SSD of claim 26 wherein the SSD further comprises a secondary source of power and said program instructions are further for writing all un-replicated changed data to the NVSM upon loss of primary power using the secondary source of power.

31. The SSD of claim 30 wherein said program instructions are further for:
maintaining the data currently stored in the VM using the secondary power source until the charge level of the secondary power source has fallen below a predetermined shutdown threshold or primary power has been restored to the SSD; and
decoupling one or more components of the SSD from the secondary power source not necessary to said maintaining.

32. The SSD of claim 31 wherein said program instructions are further for resuming said processing and said replicating when the primary power source is restored before the charge level of the secondary source has fallen below the predetermined shutdown threshold.

33. The SSD of claim 30 wherein said program instructions are further for:
repopulating the written and replicated data from the NVSM to the VM after the suspending of said maintaining and after the primary power source has been restored; and
resuming said processing I/O requests and said replicating in parallel with said repopulating until the VM is completely repopulated.

34. A solid state disk (SSD) device comprising a non-volatile storage module (NVSM) and a volatile memory (VM), said SSD further comprising: a storage means for storing program instructions, the program instructions for:
upon receiving primary power to the SSD:
populating the VM with data stored in the NVSM, the address locations for the data in the VM being associated with the data stored in the NVSM; and
processing pending I/O requests received from the host during said populating, said processing further comprising:
suspending said populating;
writing data specified with a WRITE request to one or more address locations of the VM specified with the request;
recording the written VM address locations of the WRITE request as changed;
recording the written VM address locations of the WRITE request as populated;
retrieving data from the VM when the address locations specified with a READ request are recorded as populated and returning the data to the host; and
retrieving data from the NVSM when one or more of the address locations specified with the READ request are not recorded as populated, writing the retrieved data to the VM, recording the address locations written with the retrieved data as populated and returning the data to the host.

35. The SSD of claim 34 wherein said program instructions are further for:
accessing chunks of data from the NVSM;
comparing the address locations associated with the data comprising each chunk with the address locations recorded as populated;
dropping the data from the chunk associated with address locations; and
writing the remaining data to the VM at the associated address locations.

36. The SSD of claim 34 wherein said program instructions are further for: after said populating is complete:
processing pending I/O requests received from the host during said populating, said processing further comprising:
writing data specified with a WRITE request to the address locations of the VM specified with the request;
recording the written VM address locations of the WRITE request as changed; and
replicating the changed data to their respective address locations in the NVSM when not processing pending I/O requests from the host.

37. The SSD of claim 36 further comprising a secondary source of power and wherein the said program instructions are further for writing all un-replicated changed data to the NVSM upon loss of primary power using the secondary source of power.

38. The SSD of claim 37 wherein said program instructions are further for:
maintaining the data currently stored in the VM using the secondary power source until the charge level of the secondary power source has fallen below a predetermined shutdown threshold or primary power has been restored to the SSD; and
decoupling one or more components of the SSD from the secondary power source not necessary to said maintaining.

39. The SSD of claim 38 wherein said program instructions are further for resuming said processing and said replicating when the primary power source is restored before the charge level of the secondary source has fallen below the predetermined shutdown threshold.
